(19) United States
(12) Patent Application Publication
(10) Pub. No.: US 2012/0018761 A1
(43) Pub. Date: Jan. 26, 2012

(54) PHOSPHOR MEMBER, METHOD OF MANUFACTURING PHOSPHOR MEMBER, AND ILLUMINATING DEVICE

(75) Inventor: Mika Honda, Tokyo (JP)

(73) Assignee: KONICA MINOLTA OPTO, INC., Tokyo (JP)

(21) Appl. No.: 13/257,340

(22) PCT Filed: Mar. 19, 2010
(86) PCT No.: PCT/JP2010/054799

§ 371 Date: Sep. 19, 2011

(30) Foreign Application Priority Data
Mar. 27, 2009 (JP) 2009-079973

(51) Int. Cl. H01L 33/50; B05D 5/06; B05D 3/02; H01J 1/62

(52) U.S. Cl. 257/98; 313/483; 427/157; 257/E33.061

(57) ABSTRACT

In the present invention, provided is a phosphor member capable of improving a yield and an extraction rate, in addition to high environmental tolerance, high heat resistance, high durability and a high color rendering property, by which variations of color and an amount of light are reduced, and also provided are a method of manufacturing the phosphor member and an illuminating device. Disclosed is a phosphor member prepared separately from an LED light source constituting a white illuminating device, wherein the phosphor member possesses phosphor particles and an inorganic layer having been subjected to coating and a heat treatment.

### TECHNICAL FIELD

The present invention relates to a phosphor member, a method of manufacturing the phosphor member and an illuminating device in which the phosphor member is used, and specifically to a phosphor member prepared separately from an LED light source constituting a white illuminating device, which is to produce luminescence via wavelength conversion by absorbing a part of emission from an LED chip, and, and also to a method of manufacturing the phosphor member and an illuminating device in which the phosphor member is used

### BACKGROUND

In recent years, LED chips radiating blue light emitted by a gallium nitride based compound semiconductor, or UV radiation have been developed. Development of LED emitting devices emitting light with different hue from emission color of the chip including white color has been studied by using this LED chip in combination with various phosphors. This LED emitting device offers many advantages in small size, light weight and power conservation, and is widely utilized as an alternative to a power supply for display and a small size light bulb, or as a light source for a liquid crystal panel.

As a method of forming a phosphor member in addition to the above-described LED, a method of filling a resin containing a phosphor in an installation section is conventionally used.

Further, as a conventional light emitting diode, there is one in which a light emitting diode is enclosed by a protective resin containing a phosphor, and further, the resulting is entirely enclosed by a sealing resin.

However, a conventional method of forming a phosphor section in which a resin containing a phosphor, in an LED installation section produced a problem such that complicated processes consume too much time, since a small amount of resin containing a phosphor is dripped, filled and cured in each of LED installation sections. Further, since it was difficult to control a dripping amount of resin, and a phosphor having a larger specific gravity than that of the resin appeared to tend to settle down within the curing time of the resin, differences were easily produced in settlement degree, and consequently, there appeared a problem such that color and an amount of light were largely varied in each light emitting section.

Further, a light-emitting diode enclosed by a protective resin containing the above-described phosphor, and further, in the case of the light-emitting diode entirely enclosed by s sealing resin, various practical problems are produced. With respect to the first problem, when environmental tolerance of the protective resin and the sealing resin is not always sufficient, the phosphor blended in the protective resin is limited to a specific kind of the resin. That is, when a resin generally permeates water content, and is left standing in high humidity atmosphere, the water content penetrates the inside of the resin as time passes. In this case, a light wavelength conversion function of the phosphor is often lowered or disappears via degradation or modification caused by the penetrating water content. For example, a commonly known typical calcium sulfide based phosphor to be hydrolyzed by water content prominently produces such a problem.

Accordingly, since applicable phosphors were limited to specific kinds of them, there was a problem such as a poor color rendering property or the like.

With respect to the second problem, a coating resin (protective resin or sealing resin) and the phosphor are degraded by the UV radiation component generated from a light-emitting diode. It is commonly known that in the case of a protective resin or a sealing resin composed of an organic polymeric compound in which elements such as carbon, hydrogen, oxygen, nitrogen and so forth are bonded to each other in the form of a network, the network structure of the organic polymer is broken via exposure thereof to UV radiation, whereby various kinds of optical properties and chemical properties are degraded. In the case of a blue light-emitting diode chip formed of GaN (gallium nitride), since an emission component appears in an ultraviolet wavelength range of 380 nm or less other than the visible component the coating resin gradually turns yellow from the periphery of a light-emitting diode chip exhibiting strong light intensity, and a coloring phenomenon is generated. For this reason, the visible light emitted by a light-emitting diode chip is absorbed at a colored section, and attenuates. Further, since not only moisture resistance is lowered along with degradation of a coating resin, but also ion permeability is increased, a light-emitting diode chip itself is degraded, whereby emission intensity of a light-emitting diode device is synergistically reduced. In order to avoid degradation of the coating resin caused by UV radiation, a method of adding a UV absorbent or the like into a coating resin is viewed as a method, but a UV absorbent which neither absorbs the visible light component itself, nor deteriorates an inherent property of the coating resin should be carefully selected. Further, when employing a UV absorbent, since additional material to be used and operation processes are increased, there appears a problem such as rise in product prices. Accordingly, there was a problem such as inferior environmental tolerance mainly to moisture resistance.

With respect to the third problem, because of turning yellow, and coloration of a coating resin exhibiting low heat resistance, there appears a problem such that light emitting from a light-emitting diode attenuates when its passing through a coating resin. For example, a blue light-emitting diode chip formed of GaN (gallium nitride) having a high forward voltage exhibits large power loss even in the case of considerably low forward current, and largely increases chip temperature during operation. It is commonly known that a resin is gradually degraded when it is heated to high temperature, resulting in turning yellow and coloration. Accordingly, since when a light-emitting diode chip formed of GaN is used in a conventional light-emitting diode device, a resin gradually turns yellow and colors from a part brought into contact with a light-emitting diode chip at high temperature, the external appearance and emission intensity of the light-emitting diode device are gradually lowered In this way, in the case of a conventional light-emitting diode device, the above-described problem is produced when phosphor is blended with a resin. For this reason, reduction of material kinds to be selected, drop in reliability, incompleteness in light conversion function, and rise in product prices result.

As to a conventional technology, further known is a phosphor-sealing resin in which phosphor is dispersed in a resin in the form of liquid at normal temperature (an epoxy resin, a silicone resin and so forth, for example), and is cured while heating (refer to Patent Document 1 and Patent Document 2, for example). However, since an epoxy resin was used in a phosphor-sealing resin disclosed in the above-described Patent Document 1, the epoxy resin was optically degraded when using for a long duration, resulting in generation of a problem such as durability. Further, since the resin turned yellow because of optical degradation, there appeared a problem such as a color rendering property. Since a silicone resin is used for a phosphor-sealing resin disclosed in the above-described Patent Document 2, a difference between an expansion at normal temperature (during non-emission) and another expansion at high temperature (during emission) is large When repeating the emission and the non-emission, a sealed wire (gold wire) is subjected to tensile stress. As a result, wire disconnection tends to occur, whereby no long life can be expected, resulting in appearance of a problem such as durability. Further, water content in the air is permeated to the inside of a silicone resin because of the silicone resin exhibiting high moisture permeability, whereby phosphor and a semiconductor layer appear to be often degraded, and there has appeared a problem such as environmental tolerance.

Further, as a conventional technique, it is disclosed that after glass in the form of a solid at normal temperature is melt while heating, and phosphor is mixed in the resulting, followed by cooling after putting it in a die to mold a phosphor sealing glass (refer to Patent Document 3, for example). However, in the case of the phosphor sealing glass disclosed in the above-described Patent Document 3, since a heat resistance property is to be provided for phosphor, and the phosphor to he mixed in glass having been melt while heating is limited to specific kinds, fluorescence wavelength and efficiency lead to few options. As a result, a color mixing ratio is difficult to be adjusted, and there appears a problem such as a color rendering property.

As another technique, disclosed is a chip further sealed with a sealing resin after a semiconductor emitting element is provided at the bottom of a cup section, and glass in the form of liquid in which phosphor is mixed is put into the cup section and formed via solidification while heating (refer to Patent Document 4, for example). In the case of a chip disclosed in the above-described Patent Document 4, a semiconductor emitting element is sealed by putting glass in which phosphor is mixed into the cup section to be formed via solidification, but there has been a problem such that a yield and an extraction rate caused by semiconductor failure, failure of dispersing phosphor and emission failure are low. The phosphor layer to be prepared as another different member makes it possible to improve the yield and the extraction rate.

Further, as another different technique, proposed is an LED employing a resin sheet containing phosphor (refer to Patent Document 5, for example). However, in the case of a resin sheet containing phosphor disclosed in the above-described Patent Document 5, the phosphor layer should have a thickness to a certain extent in order to obtain sufficient strength. It is difficult to evenly disperse phosphor particles in such a resin sheet, and when the phosphor particles were exccentrically located, and coagulated, there appeared a problem such that light taking-out efficiency to the outside was lowered because of light scattering, and a color rendering property was lowered when the light taking-out efficiency partially differs.

### PRIOR ART DOCUMENT

### Patent Document

Patent Document 1: Japanese Patent O.P.I. (Open to Public Inspection) Publication No. 2000-164937

Patent Document 2: Japanese Patent O.P.I. Publication No. 2003-142737

Patent Document 3: Japanese Patent O.P.I. Publication No. 2007-16171

Patent Document 4: Japanese Patent O.P.I. Publication No. 11-204838

Patent Document 5: Japanese Patent No. 4122739

### DISCLOSURE OF THE INVENTION

### Problems to be Solved by the Invention

The present invention is to solve the above-described problems, and it is an object of the present invention to provide a phosphor member capable of improving a yield and an extraction rate, in addition to high environmental tolerance, high heat resistance, high durability and a high color rendering property, by which variations of color and an amount of light are reduced, and to provide a method of manufacturing the phosphor member and an illuminating device.

### Means to Solve the Problems

As to a process of improving a yield and an extraction rate, in addition to high environmental tolerance, high heat resistance, high durability and a high color rendering property, by which variations of color and an amount of light are reduced, after considerable effort during intensive studies, the inventor has found out that the above-described object of the present invention is accomplished by the following structures.

(Structure 1) A phosphor member prepared separately from an LED light source constituting a white illuminating device, wherein the phosphor member comprises phosphor particles and an inorganic layer having been subjected to coating and a heat treatment.

(Structure 2) The phosphor member of Structure 1, wherein the inorganic layer comprises a coating film obtained by coating a coating solution containing inorganic oxide particles having an average particle diameter of not less than 1.0 nm and not more than 1.0 μm, the resulting coating film being subjected to a heat treatment.

(Structure 3) The phosphor member of Structure 1 or 2, wherein the inorganic layer comprises an inorganic layer containing a composition comprising a polysiloxane bond obtained via formation of the coating film with the coating solution containing a polysiloxane composition precursor, and the heat treatment applied to the resulting coating film.

(Structure 4) The phosphor member of any one of Structures 1-3, wherein the inorganic layer comprises the phosphor particles.

(Structure 5) The phosphor member of any one of Structures 1-3, comprising a glass substrate as a support and coated thereon, the coating film comprising the phosphor particles to obtain the inorganic layer by subsequently conducting the heat treatment for the coating film.

(Structure 6) The phosphor member of any one of Structures 1-3, comprising a resin layer and formed thereon, the inorganic layer, the resin layer in which the phosphor particles are dispersed in a silicone resin.

(Structure 7) The phosphor member of any one of Structures 1-3, comprising the inorganic layer obtained via formation of a coating film with a coating solution containing a polysiloxane composition precursor, and the heat treatment applied to the resulting coating film at 700° C.

(Structure 8) The phosphor member of Structure 7, comprising the inorganic layer obtained via formation of the coating film, and the heat treatment applied to the resulting coating film at 600° C. or less.

(Structure 9) The phosphor member of Structure 8, comprising the inorganic layer obtained via formation of the coating film, and the heat treatment applied to the resulting coating film at 500 or less.

(Structure 10) The phosphor member of any one of Structures 1-3, comprising the inorganic layer obtained via formation of a coating film with a coating solution containing inorganic oxide particles having an average particle diameter of not less than 1.0 nm and not more than 1.0 μm, and the heat treatment applied to the resulting coating film at 150° C. or less.

(Structure 11) The phosphor member of any one of Structures 3, 7, 8 and 9, wherein the polysiloxane composition precursor comprises a polysilazane compound or an alkoxysilane compound.

(Structure 12) The phosphor member of any one of Structures 1-11, wherein the phosphor particles have an average particle diameter of not less than 1.0 μm and not more than 100 μm, and the inorganic layer has a layer thickness of not more than 100 μm.

(Structure 13) The phosphor member of claim 2 or 10, wherein the inorganic oxide particles each comprise at least one compound selected from the group consisting of silica oxide, aluminum oxide, zinc oxide, titanium oxide and oxidized zirconia.

(Structure 14) The phosphor member of Structure 1, having a structure comprising a support and laminated thereon, at least two phosphor member units each comprising the phosphor particles and the inorganic layer.

(Structure 15) An illuminating device comprising an LED light source emitting light in a blue or ultraviolet wavelength range, the LED light source sealed with the phosphor member of any one of Structures 1-14.

(Structure 16) A method of manufacturing a phosphor member prepared separately from an LED light source constituting a white illuminating device, comprising the steps of forming a coating film employing a coating solution comprising phosphor particles and inorganic oxide particles having an average particle diameter of not less than 1.0 nm and not more than 1.0 ₚm, and making the resulting coating film to be subjected to a heat treatment at 150° C. or less to form an inorganic layer comprising the phosphor particles and the inorganic oxide particles.

(Structure 17) A method of manufacturing a phosphor member prepared separately from an LED light source constituting a white illuminating device, comprising the steps of forming a coating film employing a coating solution comprising phosphor particles and a polysiloxane composition precursor, and making the resulting coating film to be subjected to a heat treatment at 700° C. or less to form an inorganic layer comprising the phosphor particles and a composition comprising a polysiloxane bond.

(Structure 18) A method of manufacturing a phosphor member prepared separately from an LED light source constituting a white illuminating device, comprising the steps of forming a phosphor layer obtained by dispersing phosphor particles in a silicone resin, forming a coating film on the phosphor layer employing a coating solution comprising a polysiloxane composition precursor, and making the resulting coating film to be subjected to a heat treatment at 700° C. or less to form an inorganic layer containing a composition comprising a polysiloxane bond.

(Structure 19) A method of manufacturing a phosphor member prepared separately from an LED light source constituting a white illuminating device, comprising the steps of forming a phosphor layer obtained by dispersing phosphor particles in a silicone resin, forming a coating film employing a coating solution comprising a polysiloxane composition precursor, making the resulting coating film to be subjected to a heat treatment at 700° C. or less to form an inorganic layer containing a composition comprising a polysiloxane bond_{—} and layering the inorganic layer on the phosphor layer.

### Effect of the Invention

In the present invention, provided can be a phosphor member capable of improving a yield and an extraction rate, in addition to high environmental tolerance, high heat resistance, high durability and a high color rendering property, by which variations of color and an amount of light are reduced, and also provided a method of manufacturing the phosphor member and an illuminating device.

### BRIEF DESCRIPTION OF THE DRAWINGS

FIG. 1 is a cross-sectional view showing an example of a structure of a phosphor member in the present invention.

FIG. 2 is a cross-sectional view showing an example of another structure of a phosphor member in the present invention.

FIG. 3 is a cross-sectional view further showing example of another structure of a phosphor member in the present invention.

FIG. 4 is a cross-sectional view further showing an example of another structure of a phosphor member in the present invention.

FIG. 5 is a cross-sectional view further showing an example of another structure of a phosphor member in the present invention.

FIG. 6 is a cross-sectional view further showing an example of a structure of a white LED constituted by using a phosphor member in the present invention.

FIG. 7 is a cross-sectional view further showing another example of a structure of a white LED constituted by using a phosphor member in the present invention.

### DESCRIPTION OF THE PREFERRED EMBODIMENTS

### [Structure of Phosphor Member]

Next, a structure of a phosphor member in the present invention will be described referring to drawings.

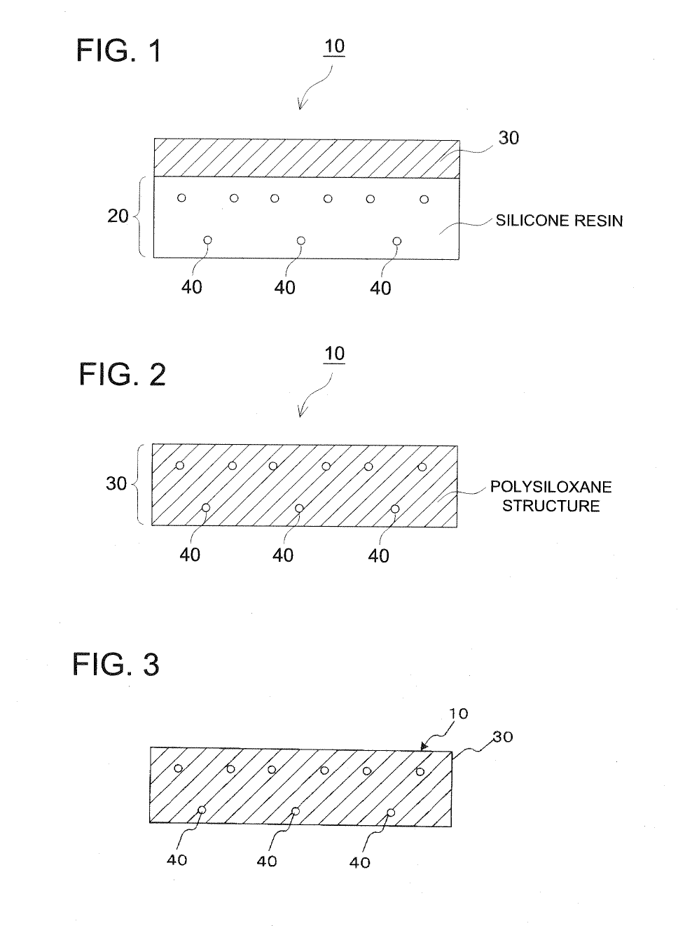

FIG. 1 is a cross-sectional view showing an example of a structure of a phosphor member in the present invention.

In FIG. 1, phosphor member 10 possesses phosphor layer 20 and layered thereon, inorganic layer 30. Inorganic layer 30 is obtained by drying liquid containing inorganic oxide particles via an annealing treatment.

Liquid containing inorganic oxide particles (for example, silicon oxide) is coated on phosphor layer 20 to form inorganic layer 30. Temperature of an annealing treatment can be set to an optimum temperature by arranging material to form an inorganic layer to be used, or desired film properties, but a temperature of 700° C. or less is preferable, a temperature of 600° C. or less is more preferable, a temperature of 500° C. or less is still more preferable, and a temperature of 150° C. or less is most preferable. A duration for the annealing treatment is determined depending on the temperature.

In the present invention, inorganic oxide particles preferably have an average particle diameter of not less than 1.0 nm and not more than 1.0 μm. The inorganic oxide particles more preferably have an average particle diameter of not less than 3.0 nm and not more than 300 nm, and most preferably have an average particle diameter of not less than 5.0 nm and not more than 100 nm.

Further, phosphor particles 40 preferably have an average particle diameter of not less than 1.0 μm and not more than 100 μm. The phosphor particles 40 more preferably have an average particle diameter of not less than 1.0 μm and not more than 20 μm. Further, inorganic layer 30 preferably has a layer thickness of 100 μm or less.

A phosphor member exhibiting excellent durability is possible to be obtained by providing an inorganic layer containing such inorganic oxide particles, since heat generated in a phosphor layer is possible to be effectively discharged into the outside while inhibiting reduction of light taking-out efficiency caused by light scattering produced from inorganic oxide particles, and the inorganic layer serves as a barrier layer in the phosphor layer. Further, thickness of the phosphor layer is possible to be reduced since strength of the phosphor member can be acquired with a phosphor layer and an inorganic layer, whereby lowering of light taking-out efficiency as well as color rendering property caused by coagulation and eccentric location of phosphor particles becomes possible to be inhibited.

FIG. 2 is a cross-sectional view showing an example of another structure of a phosphor member in the present invention.

Concerning structural components in the structure shown in FIG. 2, the same numbers as in FIG. 1 are provided, and explanations for them are omitted.

Inorganic layer 30 contains a composition possessing a polysiloxane bond and phosphor particles 40. The polysiloxane bond will be described later. Inorganic layer 30 composed of a composition possessing a polysiloxane bond and phosphor particles 40 preferably has a layer thickness of 20 μm or less, and more preferably has a layer thickness of 10 μm or less. The same effect as in foregoing structure is obtained in such a structure.

FIG. 3 is a cross-sectional view further showing an example of another structure of a phosphor member in the present invention.

As to the structure of a phosphor member shown in FIG. 3, the form of phosphor member 10 (film-shaped), an average particle diameter of inorganic oxide particles, an average particle diameter of phosphor particles 40 and layer thickness of inorganic layer 30 are in the same structure as shown in FIG. 1. The same numbers as in the structure shown in FIG. 1 are provided, and explanation thereof is omitted.

In the embodiment described in the above-described FIG. 1, phosphor layer 20 was formed by containing phosphor particles 40 in a silicone resin. In contrast, in the structure shown in FIG. 3, phosphor layer 20 was formed by containing phosphor particles 40 in inorganic layer 30. Liquid containing inorganic oxide particles (made of silicon dioxide, for example) and phosphor particles 40 is coated on a substrate (unshown in the figure), followed by calcination to form inorganic layer 30.

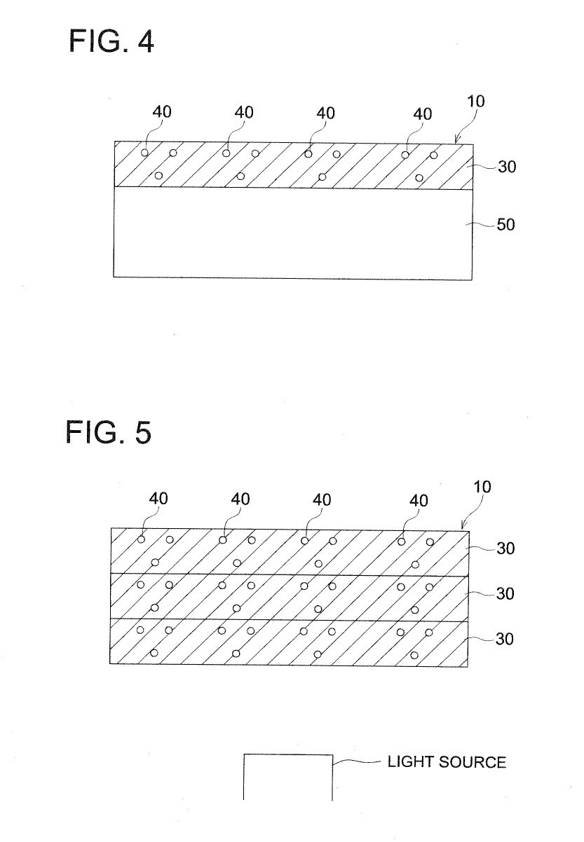

FIG. 4 is a cross-sectional view further showing an example of another structure of a phosphor member in the present invention.

Further, concerning structural components in the structure shown in FIG. 4, the same numbers as in FIGS. 1-3 are provided, and explanations for them are omitted.

As to the structure shown in FIG. 4, phosphor member 10 possesses support 50 and inorganic layer 30 layered on support 50. Inorganic layer 30 is preferably an inorganic layer containing phosphor particles 40. Support 50 preferably has a layer thickness of 20 μm or less, and more preferably has a layer thickness of 10 μm or less.

FIG. 5 is a cross-sectional view further showing an example of another structure of a phosphor member in the present invention.

FIG. 5 shows a structure in which phosphor member 10 possessing three laminated inorganic layers 30 each containing phosphor particles 40. Color tone of white light can be varied by mixing direct light in the blue or ultraviolet wavelength range, from a light source, and light having been converted by phosphor particles 40 contained in each of three laminated inorganic layers 30. Inorganic layers 30 each having a different content of phosphor particles 40 may be designated, and a structure in which a different kind of phosphor particles 40 may be used. Specifically, each of inorganic layers 30, in which phosphor particles radiating blue, green and red as the wavelength conversion material, respectively are dispersed, is laminated and used. White light is obtained by mixing these colors of light. Further, color tone of white light can be changed by varying thickness of each inorganic layer 30 in which phosphor particles of each color are dispersed. At least two layers having phosphor particles 40 radiating the same color may be laminated, and used to vary color tone of white light.

### [Illuminating Device]

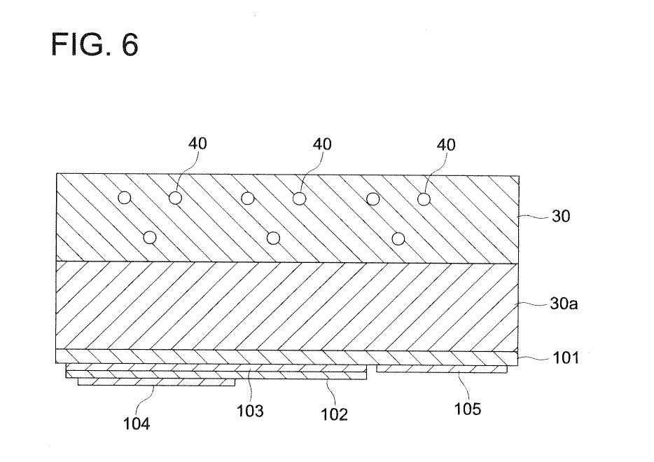

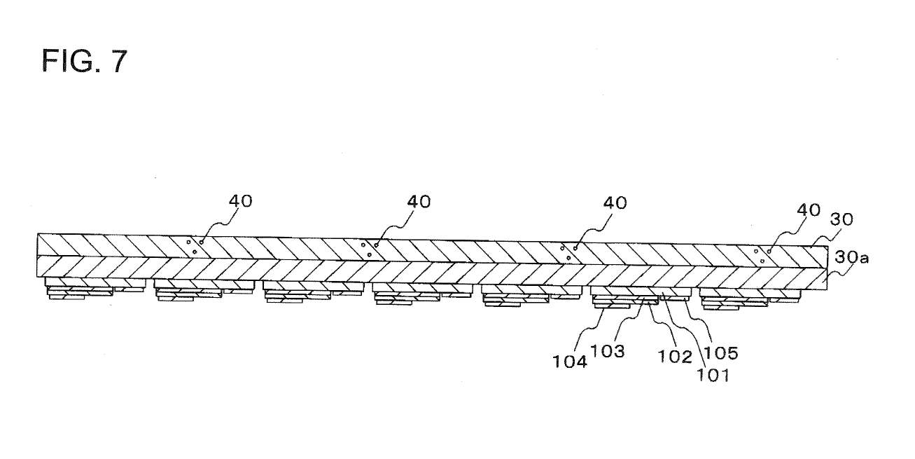

Next, the structure of an illuminating device constituted by using the above-described phosphor member will be described referring to FIG. 6 and FIG. 7.

FIG. 6 is a cross-sectional view further showing an example of a structure of a white LED constituted by using a phosphor member in the present invention.

In FIG. 6, transparent inorganic layer 30a is made of sapphire or silicon carbide. Compound semiconductor layers each made of gallium nitride, gallium indium nitride or the like are laminated on one surface thereof, that is, a p-n junction is formed with n-type semiconductor layer 101 and p-type semiconductor layer 102 provided on the surface, and a light-emitting diode in which the junction area has become emission layer 103 is formed.

In FIG. 6, p-type semiconductor layer 102 is etched to n-type semiconductor layer 101, and n-side electrode 105 is formed on exposed n-type semiconductor layer 101. On p-type semiconductor layer 102, formed is p-side electrode 104. Inorganic layer 30 in which phosphor particles 40 as the wavelength conversion material are dispersed is coated and attached onto another surface of transparent inorganic layer 30a. Each of phosphor particles 40 is a phosphor which absorbs light emitting from a light-emitting diode, and emits light of complementary color thereof For this purpose, YAG phosphor or the like is usable.

According to this structure, white light can be obtained by mixing direct light from a light-emitting diode and light converted via phosphor particles 40. This element is mounted by a flip-chip system in which the electrode side is directly connected to a wiring board.

Further, if the upper surface of a layer composed of inorganic layer 30 containing phosphor particles 40 is roughened, a drop in light taking-out efficiency caused by total reflection can be avoided. This roughened surface may be formed on the upper surface of the layer as such a shape, or some sort of particles may be mixed.

FIG. 7 is a cross-sectional view further showing another example of a structure of a white LED constituted by using a phosphor member in the present invention.

In FIG. 7, a section composed of inorganic layer 30 containing phosphor particles 40 is in the form of a sheet prepared in advance, and a uniform layer can he prepared via formation of inorganic layer 30 in advance. Preparation is easy if an inorganic layer is separately prepared when the inorganic layer is roughened, and a distribution and an amount of a wavelength conversion material is controlled. Further, plural kinds of sheet-shaped inorganic layers are kept for a certain amount of time, depending on the application, and it is also possible to continue manufacturing processes after conducting assembling via an adhesion process as needed.

Next, each constituent element of a phosphor member in the present invention will be described in detail.

### [Glass Substrate]

In the case of a phosphor member of the present invention, as to a structure in which an inorganic layer is formed on a support as shown in FIG. 4, the support is made of glass, and the inorganic layer containing phosphor particles is preferably provided on the substrate made of glass.

Substrates made of glass applicable to the present invention are not limited, but preferable is colorless and transparent glass such as glass in which an amount of silica is increased up to 96% by phase-separating borosilicate glass called commonly known “cover glass” and by eluting an amount of alkali boric acid, and “VYCOR” produced by Corning Incorporated in the United States is specifically provided. Though being inferior in heat resistance to VYCOR, PYREX (Registered Trademark) and TEMPAX produced by SCHOTT AG {almost the same composition as that of PYREX (Registered Trademark)} having a small linear expansion coefficient are transparent in the ultraviolet region, and are also preferably used for glass substrates. Further, though quartz glass is expensive, it has smaller linear expansion coefficient than that of PYREX (Registered Trademark), and exhibits an excellent property as a glass substrate by possessing a property to transmit ultraviolet light. On the other hand, glass substrates undesired to be used in the present invention are those in which conventional soda-lime glass called commonly known “liquid glass”, or the like is used, and it is not preferable that this produces absorption at a wavelength of about 350 nm, whereby no transmission of light emitted from an LED chip occurs.

### [Phosphor Particle]

It is a feature that a phosphor member of the present invention contains phosphor particles.

The phosphor particles usable in the present invention are those by which blue light emitted from a blue LED is possible to be converted into yellowish light, for example, greenish yellow (an emission peak at a wavelength of about 550 nm), and those conventionally available in the market are usable. As most preferable oxide phosphor, cited is Y₃Al₅O₁₂ such as (Y, Gd, Ce)₃Al₅O₁₂ or the

Sr₁₀(PO₄)₆Cl₂:Eu²⁺, CaS:Bi, and Ba₁₋ₐEuₐMgAl₁₀O₁₇ are provided as blue phosphor, ZnS:Cu,Al, Ba₂SiO₄:Eu, and ZnGe₂O₄:Eu are provided as green phosphor, and Y₂O₂S:Eu³⁺, CaS:Eu, 3.5MgO.0.5MgF₂.GeO₂:Mn, and K₅Eu_{2.5}(WO₄) are provided as red phosphor.

The phosphor layer containing phosphor particles in the present invention means an inorganic phosphor layer emitting via excitation generated by light emitted from at least a semiconductor emission layer in an LED chip. In the present invention, in relation to a filling rate of the inorganic phosphor, when light emitted from a LED chip and light emitted from an organic phosphor layer are in the complementary color relation ship, white light emission can be produced via color-mixing of each color.

Specifically, provided are light emitted from an LED chip and each of light’ three primary colors (red, green, blue) being light of the phosphor layer emitted via excitation with light from the LED chip; blue light emitted from an LED chip and light of the phosphor layer emitting yellow via excitation with blue light from the LED chip: and so forth.

Any color tone such as a light bulb color including white light can be provided by selecting kinds of phosphor particles used for a phosphor layer, and a main emission wavelength of an LED chip as a light-emitting element.

### [Constituent Material of Inorganic Layer (Inorganic Oxide Film)]

### (Inorganic Oxide Particles)

The composition of inorganic oxide particles in the present invention is not specifically limited, but it is preferably at least one compound selected from the group consisting of silicon oxide, aluminum oxide, zinc oxide, titanium oxide and zirconium oxide.

In the present invention, inorganic oxide particles preferably have an average particle diameter of not less than 1.0 nm and not more than 1.0 μm: more preferably have an average particle diameter of not less than 3.0 nm and not more than 300 nm; and still more preferably have an average particle diameter of not less than 5.0 nm and not more than 100 nm. In general, even though a coating film obtained from a dispersion of inorganic oxide particles in the order of micrometers in size is subjected to only a heat treatment, no strong coating film can be obtained, but in the case of the present invention, since inorganic oxide particles in the order of nanometers in size are used, reactivity is improved by increasing a specific surface area, and an inorganic film containing strong inorganic oxide can be fanned via a heat treatment. On the other hand, in the case of inorganic oxide particles having a particle diameter of 1.0 nm or less, it is difficult to obtain those per se, and particle-to-particle coagulation is to be accelerated in a short amount of time even though obtaining them, whereby the resulting situation becomes unstable, and is difficult to be applied for the present invention.

(Inorganic Layer Containing Inorganic Oxide particles)

The inorganic layer containing inorganic oxide particles in the present invention is possible to be used as an inorganic layer formed by drying and baking a dispersion of inorganic oxide particles, but it is preferred to contain a composition having at least the above-described inorganic oxide particles and a polysiloxane bond to form the after-mentioned silica based layer as constituent elements.

In this case, inorganic oxide particles in the inorganic layer preferably has a content of not less than 30% by volume and not more than 99% by volume, and more preferably has a content of not less than 50% by volume and not more than 80% by volume.

In order to determine a content of inorganic oxide particles in the inorganic layer, cross-sections of an inorganic oxide film are observed by a transmission electron microscope, and the content is designated as a ratio of the total area of inorganic particles contained in the total cross-sectional area of the inorganic oxide film. Since as to inorganic particles, the original particle interface in a film is observed, the area where inorganic particles are present is possible to be quantitated. The inorganic oxide film is possible to be formed via a dry process such as evaporation or the like, or a wet process such as a sol-gel process or the like, but since in the case of any of them, the particle interface of crystals is present, weather-resistance to gas and water vapor has not been sufficient. However, since generation of cracks causing damage of weather-resistance and durability can be minimized, it has become possible to improve weather-resistance and durability.

Solvents used for dispersing inorganic oxide particles are not specifically limited, but solvents exhibiting water solubility are preferably used.

In the present invention, after coating it on a resin substrate made of a silicone resin or the like, a method of conducting an annealing treatment at 120° C. for 30 minutes is preferably used. An inorganic layer to be coated once preferably has a layer thickness of 20 μm or less, and preferably has a layer thickness of 10 μm or less. In the case of the thickness exceeding 20 μm, film strength tends to be weakened because of insufficient dehydration condensation reaction. The film strength is endurable up to a pencil hardness of approximately 7H.

In order to adjust drying, a high boiling point solvent called GLICOAT (a boiling point of 206° C.) is usable. Drying temperature can he lowered by reducing a consumption amount.

### (Compound Possessing Polysiloxane Bond)

An inorganic layer of the present invention preferably has an embodiment in which the inorganic layer contains a composition possessing a polysiloxane bond. As a composition possessing a polysiloxane bond, a commonly known compound is usable, but a siloxane polymer is preferably usable.

The siloxane polymer in the present invention is not specifically limited, but it is preferable to be a polymer possessing a Si—O—Si bond.

### <Alkoxysilane Compound>

In the present invention, a composition possessing a polysiloxane bond, which constitutes an inorganic layer is preferably obtained by using an alkoxysilane compound as a starting material. In the present invention, a compound as the starting material to form the composition possessing a polysiloxane bond is often called a polysiloxane composition precursor. Any kind of alkoxysilane is usable as alkoxysilane. As such an alkoxysilane, a compound represented by the following Formula (a) can be provided, for example.

R¹ₙ—Si(OR²)₄₋ₙ Formula (a)

where R¹ represents a hydrogen atom, or an alkyl group or aryl group having 1-20 carbon atoms; R² represents a monovalent organic group; and n is an integer of 0-2. Herein, as the monovalent organic group represented by R², provided can be an alkyl group, an aryl group, an ally! group, a glygyl group and so forth, for example. Of these, an alkyl group and an an group are preferable. An alkyl group having carbon numbers is preferable, and a methyl group, an ethyl group, a propyl group, a butyl group and so forth can be exemplified, for example. Further, the alkyl group may be straight-chained or branched, and hydrogen atoms may be substituted by fluorine atoms. An aryl group having 6-20 carbon atoms is preferable, and a phenyl group, a naphthyl group and so forth can be provided, for example.

Specific examples of compounds represented by Formula (a) described above include in the case of (a1) n=0, letramethoxy silane, tetraethoxy silane, tetrapropoxy silane, tetrabutoxy silane and so forth; in the case of (a2) n=1, monoalkyltrialkoxy silane such as monomethyltrimethoxy silane, monomethyltriethoxy silane, monomethyltripropoxy silane, monoethyltrimethoxy silane, monoethyltriethoxy silane, monoethyltripropoxy silane, monopropyltrimethoxy silane and so forth, and monophenyltrialkoxy silane such as monophenyhrimethoxy silane, monophenyltriethoxy silane and so forth; and in the case of (a3) n=2, dialkyldialkoxy silane such as dimethyldimethoxy silane, dimethyldiethoxy silane, dimethyldipropoxy silane, diethyldimethoxy silane, diethyldiethoxy diethyldipropoxy silane, dipropyldimethoxy silane, dipropyldiethoxy silane and dipropyldipropoxy silane and so forth, and diphenyldialkoxy silane such as diphenyldimethoxy silane, diphenyldiethoxy silane and so forth.

As to a composition of an inorganic layer in the present invention, a composition possessing a polysiloxane bond preferably has a weight average molecular weight of not less than 200 and not more than 50000, and more preferably has a weight average molecular weight of not less than 1000 and not more than 3000. In the case of this range, coatability of an inorganic layer composition can be improved.

Hydrolytic condensation of alkoxysilane as a polymerization monomer is done by reacting alkoxysilane in an organic solvent in the presence of an acidic catalyst or a base catalyst. The alkoxysilane as a polymerization monomer may be condensed by using only one ldnd, or may condensed by using plural kinds in combination.

During hydrolysis, added may be trialkylalkoxysilane such as trimethyhnethoxysilane, trim ethylpropoxysilane, triethylmethoxysilane, triethylmethoxysilane, triethylpropoxysilane, tripropylmethoxysilane, tripropylethoxysilane or the like, and triphenylalkoxysilane such as triphenylmethoxysilane, triphenylethoxysilane and so forth.

A hydrolysis degreee of alkoxysilane based on condensation can be adjusted with an amount of added water, but 1.0-10.0 times moles are preferably added with respect to the number of moles of alkoxysilane represented by the foregoing Formula (a), and 1.5-8.0 times moles are more preferably added with respect to the number of moles of alkoxysilane represented by the foregoing Formula (a). When the addition amount of water is arranged to 1.0 mole or more times moles, the analysis degree can be sufficiently increased, whereby formation of a coating film can be improved. On the other hand, when the addition amount of water is arranged to 10.0 times moles or less, gelation can be avoided, whereby storage stability can be improved.

In the case of condensation of alkoxysilane represented by the foregoing Formula (a), an acidic catalyst is preferably used, and the acidic catalyst to be used is not specifically limited. Any of an organic acid and an inorganic acid to be conventionally used is usable. Examples of the organic acid include a carboxylic acid such as an acetic acid, a propionic acid, a butyric acid or the like, and examples of the inorganic acid include a a hydrochloric acid, a nitric acid, a sulfuric acid, a phosphoric acid and so forth. The acidic catalyst is directly added into a mixture of alkoxysilane with water, or an aqueous acidic solution is prepared with water employing the acidic catalyst to be added into alkoxysilane.

The hydrolytic reaction is usually completed in approximately 5-100 hours. Further, in a temperature of not less than room temperature and not more than 80° C., reaction is possible to be completed in less reaction time by producing reaction through which an aqueous acidic catalyst solution is dripped in an organic solvent containing at least one kind of alkoxysilane represented by the foregoing Formula (a). Alkoxysilane having been subjected to hydrolysis subsequently produces condensation reaction, whereby a Si—O—Si network is formed.

### <Polysilazane Compound>

Further, in the present invention, it is of a preferred embodiment that a polysilazane compound is used as a start material to obtain a composition containing a polysiloxane bond.

As the polysilazane applicable in the present invention, compounds each represented by the following Formula (1) can be provided

(R₁R₂SiNR₃)ₘ Formula (1)

wherein each of R₁, R₂ and R₃ independently represents a hydrogen atom, an alkyl group, an aryl group; a vinyl group, or a cycloalkyl group, at least one of R₁, R₂ and R₃ is a hydrogen atom; each of R₁, R₂ and R₃ is preferably a hydrogen atom; and n is an integer of 1-60.

The molecular form of polysilazane may be any form, and may be straight-chained or cyclic. Polysilazane represented by the above-described Formula (1) and a reaction accelerator, if desired, are dissolved in a solvent for coating, and the resulting is subjected to heating and an excimer light treatment or a UV light treatment for curing to prepare an inorganic layer exhibiting excellent heat resistance and weather-resistance. When conducting heat-curing after exposing it to UV radiation (for example, excimer light) including a wavelength component specifically in the range of 70-230 nm for curing, the effect of preventing penetration of water content can be effectively produced.

As the reaction accelerator, an acid, a base or the like is preferably used, but may be me used. Examples of the reaction accelerator include methyl amine, diethyl amine, N,N-diethylethanol amine, N,N-dimethylethanol amine, triethanol amine, triethanol amine, a hydrochloric acid, an oxalic acid, a fumaric acid, a sulfonic acid, an acetic acid, metal carboxylate containing nickel, iron, palladium, iridium, platinum, titanium or aluminum, and so forth, but the present invention is not limited thereto.

When employing a reaction accelerator, metal carboxylate is specifically preferable, and the addition amount is preferably 0.01-5 mol%, based on polysilazane.

As the solvent, aliphatic hydrocarbon, aromatic hydrocarbon, halogenated hydrocarbon, ethers, and esters are usable. Preferable are methylethyl ketone, tetrahydrofuran, benzene, toluene, xylene, dimethylfluoride, chloroform, carbon tetrachloride, ethylether. isopropylether, dibutylether, and ethylbutylether.

Further, since higher concentration of polysilazane is desired, but rise in concentration leads to reduced storage time of polysolazane, it is preferred that not less than 5% by volume and not more than 50% by volume of polysilazane are dissolved in a solvent.

### (Inorganic Oxide Particle as Additive)

Next, the case where inorganic oxide particles in an inorganic layer are used as additives for the additional purpose will be described.

When light of a light-emitting diode chip is scattered by mixing inorganic oxide particles in an inorganic layer provided in a phosphor member of the present invention, an amount of light of the light-emitting diode chip getting into a fluorescent material is increased to improve wavelength conversion efficiency, and a directivity angle of light emitted to the outside from a light0emitting diode device can also be expanded. Also in this case, the particle diameter of inorganic oxide particles should be used within the foregoing range, but inorganic oxide particles each having a small particle diameter and particles each having a considerably large particle diameter may be mixed and used. Further, when containing inorganic oxide particles, a binder is preferably blended to inhibit cracks in an inorganic layer. Further, when an inorganic layer containing inorganic particles is formed, it is possible to be used as a viscosity improver to increase viscosity of a coating solution. Further, in the case of addition of inorganic oxide particles, it is also possible to reduce a consumption amount of the other material to form the inorganic layer.

### [Material of Forming Inorganic Layer]

An inorganic layer in the present invention (inorganic oxide film) is preferably a silica based film, but it may be a ZrO₂ film or an Al₂O₃ film. In a method of forming a silica based film, a coating solution for forming a silica based film is first coated on a substrate. As a method of coating a composition to &inn a silica based film on a substrate, a wet coating method such as a spraying method, a spin coating method, a dip coating method, a roll coating method or the like is usable, but a spin coating method is conventionally used.

Next, a composition to form a silica based film coated on a substrate is subjected to a heat treatment at 700° C. or less. The means, temperature, time and so forth for the heat treatment arc not specifically limited, but heating on a hot plate at 700° C. or less for about 1-6 minutes may be carried out.

In the present invention, a composition to form a silica based film is heated via a heat treatment to generate an acid or a base. Hydrolysis is accelerated with this acid or base generated here, whereby an alkoxy group becomes a hydroxyl group, resulting in generation of alcohol. Since a Si—O—Si network is formed via condensation of two alcohol molecules, a dense silica based film can be obtained via a heat treatment.

Further, temperature can also be raised in a stepwise fashion by dividing the heat treatment into 3 steps in an atmosphere of inert gas such as nitrogen. In this way, silica based films can be formed at lower temperature by conducting the stepwise heat treatment in a stepwise fashion such as 3 steps, and preferably about 3-6 steps.

In the present invention, a coating film formed from a dispersion containing a polysiloxane composition precursor and inorganic oxide particles is preferably subjected to a heat treatment at a temperature of 700° C. or less.

As to a heating method, a conventionally usable heating device is applicable with no limitation, but preferably used is a heating method by which heating in a short amount of time is intermittently repeated.

In the case of a heating method in the present invention, a coating film (referred to also as a coating layer) of a dispersion containing inorganic oxide particles is subjected to local heating to form an inorganic film.

Herein, “local heating” of a coating film means that a coating layer is subjected to heating at a high temperature of 700° C. or less without any substantial degradation of a resin substrate caused by heating. For this reason, various commonly known methods can be used as the local heating method. For example, appropriately selected can be heating, hot air, microwave, ultrasonic wave, induction heating or the like. Of these, preferable are a process of intermittent exposure to infrared rays, and methods of utilizing electromagnetic wave such as microwave, and ultrasonic wave.

An exposure device such as an infrared lamp, an infrared heater or the like is usable as an infrared exposure device. Exposure once by an infrared exposure device is good enough, provided that an inorganic oxide layer can be stably formed, but preferably used is a method of repeating intermittent exposure to infrared rays in a short amount of time in order to heat a coating layer locally. As the method of repeating intermittent exposure to infrared rays in a short amount of time, provided are, for example, a method of repeating on-off of an infrared exposure device in a short amount of time, a method of conducting repetitive exposure to light by moving a shield plate after providing the shield plate between an infrared exposure device and an unexposed object, and a method of conducting repetitive exposure to infrared rays by transporting an unexposed object after providing infrared exposure devices in plural portions in the direction of transporting the unexposed object (resin film).

The microwave is a collective term of the range of UHF-EHF having approximately a wavelength of 1-300 mm and a frequency of 1 GHz-3 THz, and a microwave generator having a frequency of 2.45 GHz is conventionally used, but usable is the microwave having a frequency of 1-100 GHz. For example, exemplified are a microwave exposure device having a frequency of 2.45 GHz (μ-reactor, manufactured by Shikoku Instrumentation Co., Ltd.), a microwave generator (magnetron) having a frequency of 2.45 GHz, and so forth.

In the present invention, “ultrasonic wave” means elastic oscillation wave (sonic wave) having a vibration frequency of 10 kHz or more. As to a heating method employing ultrasonic wave applicable in the present invention, it is preferable that heating for a short amount of time is intermittently repeated at a horn frequency of 50 kHz or less.

Also in the case of heating a coating layer employing microwave or ultrasonic wave, preferably used is a method of locally heating only a resin coating layer with no degradation of a resin substrate by intermittently repeating heating in a short amount of time similarly to infrared exposure.

### EXAMPLE

Next, the present invention will be specifically described referring to Examples, but the present invention is not limited thereto. Incidentally, “parts” and “%” in Examples represent “parts by weight” and “% by weight”, respectively, unless otherwise specifically mentioned.

### Example 1

Four hundred grams of pure water was charged in a one liter stainless pot, and 600 g of silicon oxide 1 (product name: SPF-30M with an average particle diameter of 700 nm, produced by DENKI KAGAKU KOGYO KABUSHIKI KAISHA) were added therein, spending 5 minutes, at 6000 rpm, employing ULTRA-TURRAX T25 Digital (manufactured by IKA Works, Inc.), followed by dispersing for 30 minutes.

An operation, in which 1000 g of methylethyl ketone were added, and the solvent was removed at a vessel temperature of 40° C. and at reduced pressure of 26.6 kPa by an evaporator until the residual amount reached 800 g, was subsequently repeated 3 times, and finally, 200 g of methylethyl ketone were added to make the total weight to be 1000 g to obtain dispersion-1.

Next, 20 parts by weight of tetraethoxysilane {Si(C₂H₅O)₃} and 80 parts by weight of nitrile ethoxysilane {C₆H₅Si(OC₂H₅)₃} were mixed in 100 parts by weight of ethyl alcohol to produce reaction with a formic acid as a catalyst, and an acidic solution was obtained.

Next, the acidic solution was neutralized by triethylamine {(C₂H₅)₃N} to obtain a neutralized solution. Then, the neutralized solution was solution-substituted by methylethyl ketone to obtain resin solution-1 having a resin nonvolatile amount concentration of 60% and a viscosity of 400 mPa·s.

Thirty grams of dispersion-1 and 70 g of resin solution-1 were mixed to obtain mixed solution-1. Phosphor was dispersed so as to make a weight ratio of mixed solution-1 and the phosphor to be 90:10, and bar-coating was conducted on a tray having been subjected to a surface fluorination releasing treatment in such a way that a film thickness after drying became 5.0 μm, followed by heat-drying in a dry oven at 120° C. for 30 minutes to prepare Example 1 as a phosphor member in the form of a film.

### Example 2

A sample in Example 2 was prepared similarly to the sample preparation of the above-described Example 1, except that dispersion-1 was replaced by the following dispersion-2.

### <Preparation of Dispersion-2>

Dispersion-2 was prepared similarly to preparation of the above-described dispersion-1, except that silicon oxide I (product name: SPF-30M with an average particle diameter of 700 nm, produced by DENKI KAGAKU KOGYO KABUSHIKI KAISHA) was replaced by silicon oxide 2 (product name: SPF-20M with an average particle diameter of 300 nm, produced by DENKI KAGAKU KOGYO KABUSHIKI KAISHA).

### Example 3

A sample in Example 3 was prepared similarly to the sample preparation of the above-described Example I, except that dispersion-1 was replaced by the following dispersion-3.

### <Preparation of Dispersion-3>

Dispersion-3 was prepared similarly to preparation of the above-described dispersion-1, except that silicon oxide 1 (product name: SPF-30M with an average particle diameter of 700 nm, produced by DENKI KAGAKU KOGYO KABUSHIKI KAISHA) was replaced by silicon oxide 3 (product name: SICASTAR with an average particle diameter of 70 nm, produced by Corefront Corporation).

### Example 4

An operation, in which 60 g of an aqueous aluminum oxide dispersion (product name: NANOBYK-3600 with an average particle diameter of 40 nm, produced by Tetsutani & Co. Ltd.) and 1000 g of methylethyl ketone were added, and the solvent was emoved at a vessel temperature of 40° C. and at reduced pressure of 26.6 kPa by an evaporator until the residual amount reached 800 g. was repeated 3 times, and finally, 200 g of methylethyl ketone were added to make the total weight to be 1000 g to obtain dispersion-4.

Phosphor was dispersed so as to make a weight ratio of dispersion-4 and phosphor to be 95:5, and bar-coating was conducted in such a way that a film thickness after drying became 100 am, followed by heat-drying in a dry oven at 150° C. for 20 minutes to prepare a sample in Example 4.

### Example 5

Phosphor was dispersed so as to make a weight ratio of a viscosity liquid and phosphor in the viscosity liquid to be 95:5, the viscosity liquid in which equal parts of LPS-L402A and LPS-L402B as silicone based thermosetting resin compositions produced by Shin-Etsu Chemical Co. Ltd. are mixed, followed by thermally curing at 150° C. for 20 minutes to obtain a phosphor sheet having a thickness of 100 μm. Bar-coating was conducted on the one surface side of this phosphor sheet in such a way that as to dispersion-1 prepared in Example 1, a film thickness after drying became 5 pm, followed by heat-drying in a dry oven at 120° C. for 30 minutes to prepare a sample in Example 5.

### Example 6

Dispersion-1 described in Example 1 was bar-coated on a tray having been subjected to a surface fluorination releasing treatment so as to make thickness of a coating film after drying to be 5.0 pm, followed by heat-drying in a dry oven at 120° C. for 10 minutes. Next, after removing the resulting from the oven to remove from the heat, dispersion-1 was bar-coated so as to make thickness of a coating film after drying to be 10 pm, followed by heat-drying at 120° C. for 20 minutes to prepare a sample in Example 6.

### Example 7

Employed is (Y, Gd, Ce)₃Al₅O₁₂ yellow phosphor particles having a particle diameter distribution of 10-30 pm and an average particle diameter of 20 μm.

In one gram of AQUAMICA NL 120 (a dibutylether solution of 20% by weight of polysilazane, which contains a palladium based catalyst, produced by AZ Electronic Materials S.A.), mixed were 0.8 g of the above-described yellow phosphor particles. After dripping the resulting in an LED storage section, and precipitating yellow phosphor particles after still standing for one minute, a layer containing no yellow phosphor particle was extracted by a micropipette, subsequently followed by calcination at 100° C. for one hour to prepare a sample in Example 7.

### Example 8

In one gram of AQUAMICA NL 120 (a dibutylether solution of 20% by weight of polysilazane, which contains a palladium based catalyst, produced by AZ Electronic Materials S.A.), mixed were 0.8 g of yellow phosphor particles described in Example 7. After dripping the resulting in an LED storage section, and precipitating yellow phosphor particles after still standing for one minute, a layer containing no yellow phosphor particle was extracted by a micropipette, subsequently followed by drying at 100° C. for 10 minutes, and the resulting was exposed to Xe2 excimer radiation of 30 m Wcm² for curing, and was subsequently subjected to calcination at 250° C. for 10 minutes to prepare a sample in Example 8.

### Example 9

In one gram of AQUAMICA NN 120 (a dibutylether solution of 20% by weight polysilazane, which contains no catalyst, produced by AZ Electronic Materials S.A.), mixed were 0.8 g of yellow phosphor particles described in Example 7. After dip coating the resulting on a glass substrate having a thickness of 1 mm, and precipitating yellow phosphor particles after still standing for one minute, a layer containing no yellow phosphor particle was extracted by a micropipette, subsequently followed by calcination at 250° C. for one hour.

### Comparative example 1

As a photopolymerization compound, 14 parts by weight of a tris (3-carboxypropyl) isocyanuric acid were added into a mixture composed of 13 parts by weight of oxetanyl silsesquioxane (OX-SQ, an oxetane compound) produced by TOAGOSEI Co., Ltd.; 13 parts by weight of oxetanyl disiloxane (OX-SQ, an oxetane compound) produced by TOAGOSEI Co., Ltd.; 13 parts by weight of hexahydrophthalic acid diglycidyl ester (SR-HHPA, a glycidyl ester based epoxy resin) produced by Sakamoto Yakuhin Kogyo Co., Ltd.; 27 parts by weight of an alicyclic epoxy resin (CELLOXIDE 2081) produced by DAICEL Chemical Inductries, Ltd.: and 20 parts by weight of 4-methylhexahydrophthalic anhydride (RIKACID MH-1-700, an acid anhydride hardener) produced by New Japan Chemical Co., Ltd., and was heated while stirring and completely dissolved.

With the mixture having been cooled to room temperature, sufficiently mixed were 0.2 parts by weight of trimethoxyboroxine as a hardening accelerator, and an epoxy resin in the mixture and phosphor were mixed so as to make a weight ratio to be 15:85. A phosphor-containing epoxy resin obtained in this way was filled in the concave portion of a package, in which a light-emitting diode chip was connected to a pair of lead electrodes through gold wires, via potting, followed by thermally curing via heating at 150° C. for 2 hours to prepare a sample in Comparative example 1.

In the case of Comparative example 1. when sealing is carried out while maintaining the situation where air bubbles are mixed in an epoxy resin, the air bubbles make light from an LED chip as well as light emitted from a phosphor material to be catadioptic, whereby color unevenness and luminance unevenness have been largely observed. A process of defoaming the epoxy resin by repeating reduced pressure and applied pressure has been positively desired to be designed in order to suppress color unevenness and luminance unevenness. Further, when containing air bubbles in the epoxy resin, this causes peeling of the epoxy resin as well as the adhesion portion of wire, and broken wire and so forth, whereby reliability has been lowered.

### Comparative Example 2

Prepared was a mixture in which phosphor in the form of powder was mixed and dispersed in powder glass having a glass transition temperature Tg of 500° C., a melting point of 800° C., and an average particle diameter of 10 nm-200 μm. The phosphor in the form of powder is YAG, and those having an average particle diameter of 10 nm-200 μm similarly to the powder glass. By mixing the powder glass and the phosphor in the form of powder so as to make a weight ratio to be 100:40 while sufficiently stirring, the phosphor in the form of powder is rough-evenly dispersed in the powder glass. This powder glass contains 56-63% by weight of P₂O₅, 5-13% by weight of Al₂O₃ and 21-41% by weight of ZnO; further, 0-6% by weight of each of B₂O₃, Na₂O, K₂O, Li₂O, MgO, WO₃, Gd₂O₃ and ZrO₂; 0-12% by weight of each of CaO and Sra, and 0-22% by weight of each of BaO, TiO₂. Nb₂O₅ and Bi₂O₃. A mixture material of the powder glass and the phosphor in the form of powder is filled in the concave portion (cup portion) having an opening present on the upper side to seal a light-emitting diode chip.

After filling the power in, the resulting was placed in a dry oven, followed by heating up to temperature lower than the melting temperature of the powder glass, at not less than glass transition temperature of the powder glass, and the temperature was slowly raised up to about 560° C. Phosphor was incorporated in softened glass at a maximum temperature of 560° C.

The semiconductor substrate as a light-emitting diode was completely sealed in the softened glass so as to have a structure where it was sealed from the outside, and the softened glass was solidified via cooling to obtain a sample in Comparative example 2.

As to Comparative example 2 prepared above, the phosphor exposed to a temperature of 560° C. looks like temporarily receiving no thermal influence, but the element having been doped in the phosphor was degraded, and the emission efficiency was dropped to around 80% of the initial value in the case of continuous lighting of 5000 hours.

### Comparative Example 3

In a polypropylene beaker, 0.04 moles of tetraethoxysilane as a sol solution in which an organometallic compound is used as raw material is weighed and charged. While stirring, 0.25 moles of ethyl alcohol were added into this solution, followed by stirring for 10 minutes employing a magnetic stirrer. Further, 0.24 moles of pure water were added therein while stirring for 10 minutes, and 1 ml of 1 mol/L of HO was subsequently added therein to prepare a coating type glass material.

After evenly dispersing phosphor, the coating type glass material containing the phosphor prepared above was introduced into the inside of a concave portion (cup portion) having an opening present on the upper side, from the upper portion of a light-emitting diode chip, followed by calcination at about 150° C. for 150 minutes to form a glass layer containing the phosphor via solidification.

In order to bake sol solution-1 having been filled in down to the inside of a cup, 5 times longer heating time than that of a thin film glass layer were consumed. During preparation, calcination temperature for the glass layer was sufficiently lower temperature than the melting point of a light-emitting diode chip but degradation of the light-emitting diode chip was accelerated because of thermal history and heat storage. Neither rise in manufacturing efficiency, nor longer life of a light-emitting diode chip can be expected.

### <<Evaluation>>

Each of phosphor members prepared in Examples 1-9 and Comparative examples 1-3 described above was attached to a blue light-emitting diode chip having an emission peak at a wavelength of 470 rim to prepare each white LED.

Next, after continuously lighting this white LED for 5000 hours, in order to determine durability, whether or not performance specified below is possible to be maintained has been checked.

(1) Luminosity: 1250 (mcd) or more

(2) Emission efficiency: 70 (lm/W) or more

(3) Phosphor emission half-value width: 150 (nm) or less

When satisfying all the performances specified by 3 items described above, the basic performance for a white LED is sufficient, and is determined as “pass”. When not satisfying at least one of the performances specified by 3 items described above, the basic performance for a white LED is problematic, and is determined as “fail”.

In addition, specific measuring methods for the above-described 3 items are as follows.

### <Luminosity Measurement>

The luminosity was measured employing an integrating sphere in accordance with a method specified by JIS C 8152 (Measuring methods of white light emitting diode for general lighting).

<Emission efficiency Measurement>

Light output was measured via application of constant forward current in accordance with a method specified by MC-747-5 (Measuring methods of light emitting diodes for fiber optic transmission: JIS C 5951-1989) to calculate emission efficiency.

### <Phosphor Emission Half-Value Width Measurement>

Fluorescence spectrum half-value width of phosphor was measured with a spectrophotometer.

The results obtained from the above-described are shown in Table 1.

TABLE 1

| | | Emission | Half-value | | |
|---|---|---|---|---|---|
| | Luminosity | efficiency | width | Determina- | |
| Phosphor member No. | (mcd) | (lm/W) | (nm) | tion | Remarks |
| Example 1 | 1300 | 90 | 90 | Pass | Present invention |
| Example 2 | 1310 | 95 | 100 | Pass | Present invention |
| Example 3 | 1320 | 95 | 112 | Pass | Present invention |
| Example 4 | 1510 | 85 | 115 | Pass | Present invention |
| Example 5 | 1300 | 90 | 100 | Pass | Present invention |
| Example 6 | 1500 | 85 | 120 | Pass | Present invention |
| Example 7 | 1580 | 95 | 85 | Pass | Present invention |
| Example 8 | 1500 | 92 | 90 | Pass | Present invention |
| Example 9 | 1500 | 90 | 90 | Pass | Present invention |
| Comparative example 1 | 1000 | 75 | 150 | Fail | Comparative example |
| Comparative example 2 | 1300 | 75 | 200 | Fail | Comparative example |
| Comparative example 3 | 1200 | 65 | 130 | Fall | Comparative example |

As is clear from Table 1, it can be confirmed that Examples 1-9 of the present invention satisfy the specified condition with respect to any of luminosity, emission efficiency and phosphor emission half-value width, and exhibit sufficient durability together with achieved balance.

On the other hand, Comparative examples 1-3 do not satisfy the specified condition of at least one of the performances specified by the 3 items because of degradation of a sealing resin, degradation of phosphor and decline in emission efficiency.

### EXPLANATION OF NUMERALS

10 Phosphor member
20 Phosphor layer
30, 30a Inorganic layer
40 Phosphor particle
50 Support

1. A phosphor member prepared separately from an LED light source constituting white illuminating device,
wherein the phosphor member comprises phosphor particles and an inorganic layer having been subjected to coating and a heat treatment.

2. The phosphor member of claim 1,
wherein the inorganic layer comprises a coating film obtained by coating a coating solution containing inorganic oxide particles having an average particle diameter of not less than 1.0 nm and not more than 1.0 μm, the resulting coating film being subjected to a heat treatment.

3. The phosphor member of claim 1,
wherein the inorganic layer comprises an inorganic layer containing a composition comprising a polysiloxane bond obtained via formation of the coating film with the coating solution containing a polysiloxane composition precursor, and the heat treatment applied to the resulting coating film.

4. The phosphor member of claim 1,
wherein the inorganic layer comprises the phosphor particles.

5. The phosphor member of claim 1, comprising a glass substrate as a support and coated thereon, the coating film comprising the phosphor particles to obtain the inorganic layer by subsequently conducting the heat treatment for the coating film.

6. The phosphor member of claim 1, comprising a resin layer and formed thereon, the inorganic layer, the resin layer in which the phosphor particles are dispersed in a silicone resin.

7. The phosphor member of claim 1, comprising the inorganic layer obtained via formation of a coating film with a coating solution containing a polysiloxane composition precursor, and the heat treatment applied to the resulting coating film at 700° C.

8. The phosphor member of claim 7, comprising the inorganic layer obtained via formation of the coating film, and the heat treatment applied to the resulting coating film at 600° C. or less.

9. The phosphor member of claim 8, comprising the inorganic layer obtained via formation of the coating film, and the heat treatment applied to the resulting coating film at 500° C. or less.

10. The phosphor member of claim 1, comprising the inorganic layer obtained via formation of a coating film with a coating solution containing inorganic oxide particles having an average particle diameter of not less than 1.0 nm and not more than 1.0 μm, and the heat treatment applied to the resulting coating film at 150° C. or less.

11. The phosphor member of claim 3,
wherein the polysiloxane composition precursor comprises a polysilazane compound or an alkoxysilane compound.

12. The phosphor member of claim 1,
wherein the phosphor particles have an average particle diameter of not less than 1.0 μm and not more than 100 μm, and the inorganic layer has a layer thickness of not more than 100 μm.

13. The phosphor member of claim 2,
wherein the inorganic oxide particles each comprise at least one compound selected from the group consisting of silica oxide, aluminum oxide, zinc oxide, titanium oxide and zirconium oxide.

14. The phosphor member of claim 1, having a structure comprising a support and laminated thereon, at least two phosphor member units each comprising the phosphor particles and the inorganic layer.

15. An illuminating device comprising an LED light source emitting light in a blue or ultraviolet wavelength range, the LED light source sealed with the phosphor member of claim 1.

16. A method of manufacturing a phosphor member prepared separately from an LED light source constituting a white illuminating device, comprising the steps of:
forming a coating film employing a coating solution comprising phosphor particles and inorganic oxide particles having an average particle diameter of not less than 1.0 nm and not more than 1.0 μm, and
making the resulting coating film to be subjected to a heat treatment at 150° C. or less to form an inorganic layer comprising the phosphor particles and the inorganic oxide particles.

17. A method of manufacturing a phosphor member prepared separately from an LED light source constituting a white illuminating device, comprising the steps of:
forming a coating film employing a coating solution comprising phosphor particles and a polysiloxane composition precursor, and
making the resulting coating film to be subjected to a heat treatment at 700° C. or less to form an inorganic layer comprising the phosphor particles and a composition comprising a polysiloxane bond.

18. A method of manufacturing a phosphor member prepared separately from an LED light source constituting a white illuminating device, comprising the steps of:
forming a phosphor layer obtained by dispersing phosphor particles in a silicone resin,
forming a coating film on the phosphor layer employing a coating solution comprising a polysiloxane composition precursor, and
making the resulting coating film to be subjected to a heat treatment at 700° C. or less to form an inorganic layer containing a composition comprising a polysiloxane bond.

19. A method of manufacturing a phosphor member prepared separately from an LED light source constituting a white illuminating device, comprising the steps of:
forming a phosphor layer obtained by dispersing phosphor particles in a silicone resin,
forming a coating film employing a coating solution comprising a polysiloxane composition precursor,
making the resulting coating film to be subjected to a heat treatment at 700° C. or less to form an inorganic layer containing a composition comprising a polysiloxane bond, and
layering the inorganic layer on the phosphor layer.
